(19) United States
(12) Patent Application Publication
(10) Pub. No.: US 2013/0056352 A1
(43) Pub. Date: Mar. 7, 2013

(54) MEDIUM FREQUENCY MAGNETRON SPUTTERING DEVICE

(71) Applicants: HSIN-PEI CHANG, Tu-Cheng (TW); TENG-TSUNG HUANG, Tu-Cheng (TW); LI-QUAN PENG, Shenzhen City (CN)

(72) Inventors: HSIN-PEI CHANG, Tu-Cheng (TW); TENG-TSUNG HUANG, Tu-Cheng (TW); LI-QUAN PENG, Shenzhen City (CN)

(73) Assignees: HON HAI PRECISION INDUSTRY CO., LTD., Tu-Cheng (TW); HONG FU JIN PRECISION INDUSTRY (ShenZhen) CO., LTD., Shenzhen City (CN)

(21) Appl. No.: 13/441,282

(22) Filed: Apr. 6, 2012

(30) Foreign Application Priority Data
Sep. 6, 2011 (CN) 201110262076.8

(51) Int. Cl. C23C 14/35

(52) U.S. Cl. 204/298.12; 204/298.16

(57) ABSTRACT

A medium frequency magnetron sputtering device comprises a vacuum chamber, a rotary rack located in the center of the vacuum chamber, a pair of targets located between the inner wall of the vacuum chamber and the rotary rack, an inner partition, and at least one outer partition. The inner partition is located between the inner wall of the vacuum chamber and the pair of targets, the at least one outer partition is moveable and prevents the deposition of any sputtered target atoms on the rotary rack during the cleaning target process.

### BACKGROUND

1. Technical Field

The disclosure relates to a medium frequency magnetron sputtering device.

2. Description of Related Art

During the PVD (Physical Vapor Deposition) process, reaction gases are usually fed into a vacuum chamber of a coating device, and the reaction gases react with the sputtered target atoms. However, the reaction gases can sometimes directly react with the target when the amount of the reaction gases fed into the vacuum chamber is large, forming compounds on the surface of the target, thereby polluting the target. So there is need to clean the target. The cleaning target method is using argon gas to sputter the target in the vacuum chamber under vacuum condition, and compounds on the target will deviate from the target.

For a medium frequency magnetron sputtering device of related art, the cleaning target process needs to evacuate the vacuum chamber, and the subsequent coating process also needs to evacuate the vacuum chamber, which significantly reduces the coating efficiency.

Therefore, there is room for improvement within the art.

### BRIEF DESCRIPTION OF THE FIGURE

Many aspects of the medium frequency magnetron sputtering device can be better understood with reference to the following drawings. The components in the drawings are not necessarily drawn to scale, the emphasis instead being placed upon clearly illustrating the principles of the medium frequency magnetron sputtering device. Moreover, in the drawings like reference numerals designate corresponding parts throughout the several views. Wherever possible, the same reference numbers are used throughout the drawings to refer to the same or like elements of an embodiment.

FIG. 1 is a cross-sectional view of a first exemplary embodiment of medium frequency magnetron sputtering device.

FIG. 2 is a cross-sectional view of the medium frequency magnetron sputtering device of FIG. 1, but showing another state.

FIG. 3 is a cross-sectional view of a second exemplary embodiment of medium frequency magnetron sputtering device;

FIG. 4 is a cross-sectional view of the medium frequency magnetron sputtering device of FIG. 3, but showing another state.

### DETAILED DESCRIPTION

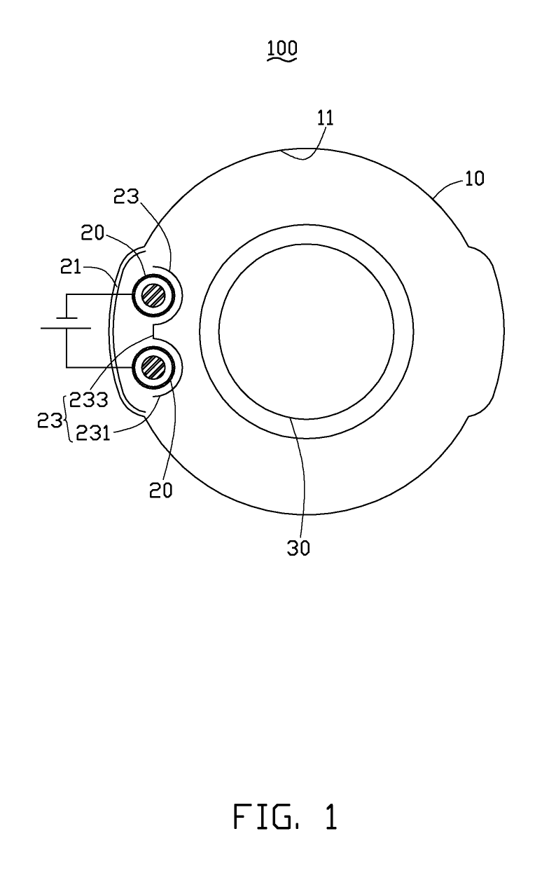

FIG. 1 shows a medium frequency magnetron sputtering device 100 according to a first exemplary embodiment. The medium frequency magnetron sputtering device 100 includes a vacuum chamber 10, and a rotary rack 30, two targets 20, an inner partition 21 and two outer partitions 23 located in the vacuum chamber 10. For the medium frequency magnetron sputtering device 100, targets 20 must be in pairs.

The rotary rack 30 is located in the center of the vacuum chamber 10. The vacuum chamber 10 has an inner wall 11. The two targets 20 are located between the inner wall 11 and the rotary rack 30. The targets 20 are cylindrical.

The inner partition 21 is located between the inner wall 11 and the targets 20. The inner partition 21 prevents target atoms being deposited on the inner wall 11 during the sputtering process of the targets 20.

Each outer partition 23 is located around a target 20 and is capable of moving around the target 20 driven by a power source. Each outer partition 23 includes an arc-shaped main body 231 and a plate-shaped connection 233 extending from one end of the main body 231. The cross-section of the main body 231 is semi-circular. The cross-sections of the main body 231 and the target 20 are coaxial.

FIG. 1 shows the closed state of the two outer partitions 23, and the two connections 233 interact to form a single wall. The inner partition 21 is roughly plate-shaped. The length of the inner partition 21 is equal or greater than the length of the two outer partitions 23 in closed state. The longitudinal heights of the inner partition 21 and the outer partitions 23 are equal or greater than the longitudinal height of the target 20.

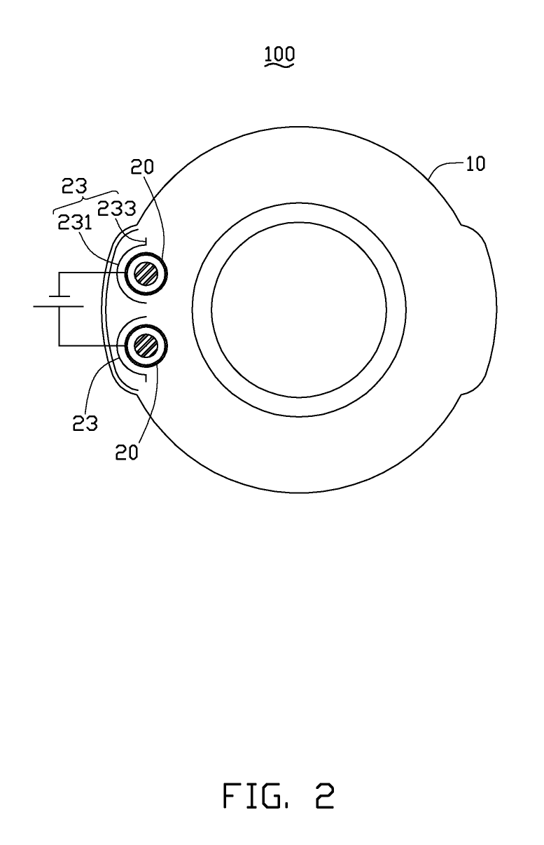

In use, substrates (not shown) are installed on the rotary rack 30, and the vacuum chamber 10 is closed and evacuated of air to a desired degree of vacuum. The two outer partitions 23 are closed to form a single wall that encloses the two targets 20 between the inner partition 21 and the outer partition 23. The two targets 20 are supplied with electrical power. Argon gas is fed into the vacuum chamber 10 to clean the targets 20. During the cleaning process, the sputtered target atoms are deposited on the inner partition 21 and the outer partition 23, so the substrate and the inner wall 11 will not be polluted. As shown in FIG. 2, the two outer partitions 23 are moved approximately one hundred and eighty degrees to a position near the inner partition 21 when the cleaning of targets 20 has been completed, and the coating process can be started immediately.

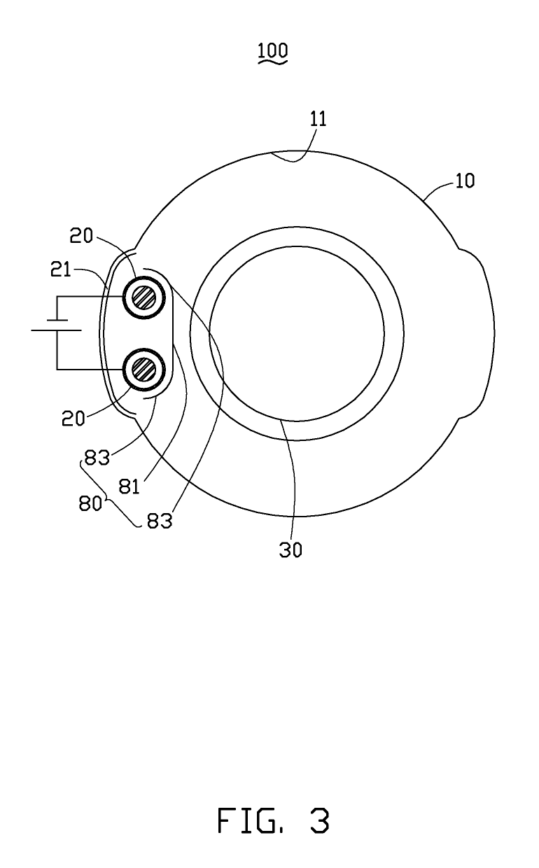

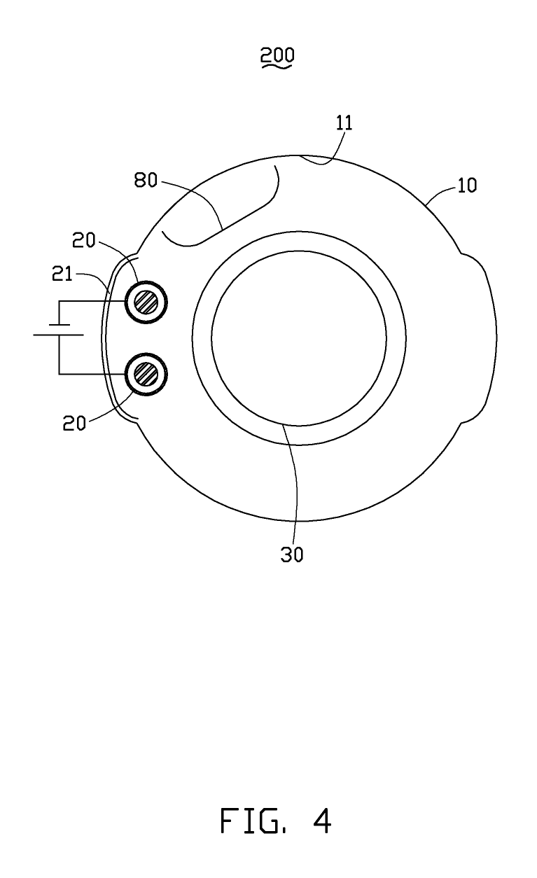

FIG. 3 shows a medium frequency magnetron sputtering device 200 according to a second exemplary embodiment. The medium frequency magnetron sputtering device 200 not only includes the same vacuum chamber 10, rotary rack 30, two targets 20, and inner partition 21 as in the first exemplary embodiment, but also includes only one outer partition 80 for enclosing the two targets 20. The outer partition 80 includes a plate-shaped main partition 81 and two arc-shaped side partitions 83 extending from the two ends of the main partition 81. The outer partition 80 is capable of moving driven by a power source. When cleaning the targets 20, the outer partition 80 is moved to a position between the two targets 20 and the rotary rack 20. When coating the substrate, the outer partition 80 is moved to a position near the inner wall 11 and spaced from the targets 20 as shown in FIG. 4. The structure of the outer partition 80 is not limited as shown in FIG. 3 and FIG. 4.

For the medium frequency magnetron sputtering device 100 and 200, the vacuum chamber 10 needs to be evacuated once for the cleaning target process and the subsequent coating process, which significantly improves the efficiency of the coating operation.

It is believed that the exemplary embodiment and its advantages will be understood from the foregoing description, and it will be apparent that various changes may be made thereto without departing from the spirit and scope of the disclosure or sacrificing all of its advantages, the examples hereinbefore described merely being preferred or exemplary embodiment of the disclosure.

What is claimed is:

1. A medium frequency magnetron sputtering device comprising:
a vacuum chamber;
a rotary rack located in the center of the vacuum chamber;
at least a pair of targets located between the inner wall of the vacuum chamber and the rotary rack;
an inner partition located between the inner wall of the vacuum chamber and each pair of targets; and
at least one outer partition corresponding to each pair of targets,
wherein the at least one outer partition is moveable, each pair of targets is located between the inner partition and the at least one outer partition when the at least one outer partition moves to a position between the pair of targets and the rotary rack, to prevent the sputtered target atoms from being deposited on the rotary rack when cleaning the targets.

2. The medium frequency magnetron sputtering device as claimed in claim 1, wherein the targets are cylindrical.

3. The medium frequency magnetron sputtering device as claimed in claim 2, wherein the at least one outer partition comprises two outer partitions, each outer partition locates around a target and is capable of moving around the target.

4. The medium frequency magnetron sputtering device as claimed in claim 3, wherein each outer partition includes an arc-shaped main body and a plate-shaped connection extending from one end of the main body.

5. The medium frequency magnetron sputtering device as claimed in claim 4, wherein the cross-section of the main body is semi-circular, the cross-sections of the main body and the targets are coaxial.

6. The medium frequency magnetron sputtering device as claimed in claim 4, wherein the two connection interact to form a single wall when the two outer partitions moves to a position between the targets and the rotary rack.

7. The medium frequency magnetron sputtering device as claimed in claim 6, wherein the length of the inner partition is equal or greater than the length of the two outer partitions connecting together.

8. The medium frequency magnetron sputtering device as claimed in claim 1, wherein the at least one outer partition comprises an outer partition, the outer partition comprises a plate-shaped main partition and two arc-shaped side partition extending from the two ends of the main partition.

9. The medium frequency magnetron sputtering device as claimed in claim 1, wherein the longitudinal heights of the inner partition and the outer partitions are equal or greater than the longitudinal height of the target.

10. A medium frequency magnetron sputtering device comprising:
a vacuum chamber;
a rotary rack located in the center of the vacuum chamber;
an inner partition located adjacent to the inner wall of the vacuum chamber; and
at least one outer partition moveably located in the chamber;
wherein a receiving space is formed between the inner partition and the at least one outer partition when the at least one outer partition moves to a position near the rotary rack, to prevent the sputtered target atoms from being deposited on the rotary rack during the cleaning target process.

11. The medium frequency magnetron sputtering device as claimed in claim 10, wherein the at least one outer partition comprises two outer partitions.

12. The medium frequency magnetron sputtering device as claimed in claim 11, wherein each outer partition includes an arc-shaped main body and a plate-shaped connection extending from one end of the main body.

13. The medium frequency magnetron sputtering device as claimed in claim 12, wherein the cross-section of the main body is semi-circular.

14. The medium frequency magnetron sputtering device as claimed in claim 12, wherein the two connections interact to form a single wall when the two outer partitions moves near the rotary rack.

15. The medium frequency magnetron sputtering device as claimed in claim 14, wherein the length of the inner partition is equal or greater than the length of the two outer partitions connecting together.

16. The medium frequency magnetron sputtering device as claimed in claim 10, wherein the at least one outer partition comprises an outer partition, the outer partition comprises a plate-shaped main partition and two arc-shaped side partition extending from the two ends of the main partition.

17. The medium frequency magnetron sputtering device as claimed in claim 10, wherein the longitudinal heights of the inner partition and the outer partitions are equal or greater than the longitudinal height of the target.
